(19) United States
(12) Patent Application Publication
(10) Pub. No.: US 2013/0337614 A1
(43) Pub. Date: Dec. 19, 2013

(54) METHODS FOR MANUFACTURING A CHIP PACKAGE, A METHOD FOR MANUFACTURING A WAFER LEVEL PACKAGE, AND A COMPRESSION APPARATUS

(71) Applicants: Edward Fuergut, Dasing (DE); Ralf Wombacher, Burglengenfeld (DE)

(72) Inventors: Edward Fuergut, Dasing (DE); Ralf Wombacher, Burglengenfeld (DE)

(73) Assignee: INFINEON TECHNOLOGIES AG, Neubiberg (DE)

(21) Appl. No.: 13/517,847

(22) Filed: Jun. 14, 2012

(51) Int. Cl. H01L 21/56

(52) U.S. Cl. 438/124; 425/520; 257/E21.502

(57) ABSTRACT

Various embodiments provide a method for manufacturing a chip package, the method including: forming an encapsulation material over a chip; compressing an encapsulation material over a chip by a film arranged over the encapsulation material, thereby molding the encapsulation material over the chip; wherein a material from the film is deposited over at least part of the encapsulation material.

### TECHNICAL FIELD

Various embodiments relate generally to methods for manufacturing a chip package, a method for manufacturing a wafer level package and a compression apparatus.

### BACKGROUND

In various technologies, e.g. chip packaging technologies, copper may be laminated as a foil. In embedded wafer level ball grid array (eWLB) technologies, copper may first be sputtered as a seed layer, and then grown by means of electroplating galvanically. The deposition of copper may generally be required for electrical interconnects in chip packages. Generally, lamination may incur higher materials costs, and may furthermore lead to costly automization, e.g. complete automization is generally not possible. Furthermore, lamination may be associated with longer processing times, e.g. approximately up to 3 hours. Sputtering is generally also a costly process, and may incur a long process time.

### SUMMARY

Various embodiments provide a method for manufacturing a chip package, the method including: forming an encapsulation material over a chip; compressing an encapsulation material over a chip by a film arranged over the encapsulation material, thereby molding the encapsulation material over the chip; wherein a material from the film is deposited over at least part of the encapsulation material.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a method for manufacturing a chip package according to an embodiment;

FIGS. 2A to 2D show a method for manufacturing a chip package and a compression apparatus according to an embodiment;

FIGS. 3A to 3C show a method for manufacturing a chip package according to an embodiment;

FIGS. 4A and 4B show a method for manufacturing a chip package and a compression apparatus according to an embodiment.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

In power electronics, trends lean towards smaller housing technologies with minimal power losses. The connection techniques with the smallest resistance, e.g. first level interconnects, is the galvanic contact. Modern housing technologies, e.g. chip embedding technologies such as embedded wafer level ball grid array (eWLB), and Chip in Substrate technology, may be based generally on galvanic contacts. However, the deposition of galvanic contacts, which may include sputtering and plating may be cost and time intensive.

According to various embodiments, the costly processes, e.g. lamination and/or sputtering, may be replaced by a compression mold process. According to various embodiments, this may reduce the cycle time from approximately 180 min (for lamination processes) to 5 min, and may make it possible, additionally, for the automated application of the copper foil, without a need for a special apparatus to be constructed or to be obtained.

According to various embodiments, instead of depositing copper on the mold compound using convention sputter processes, electrically conductive materials, such as copper may be directly applied with compression molding.

According to various embodiments, fewer process steps may be needed than with conventional eWLB contact formation, which conventionally requires sputtering and plating.

According to various embodiments, automized process execution may be possible, as chip embedding technologies such as embedded wafer level ball grid array (eWLB), and Chip in Substrate technology, which may use foil lamination, may generally be expensive to automize

According to various embodiments, an automold process with small modifications (FAME unit) may be used for depositing electrical contacts, and further tool investment may not be necessary.

According to various embodiments, an electrically conductive foil, e.g. a metal foil may be applied with compression molding.

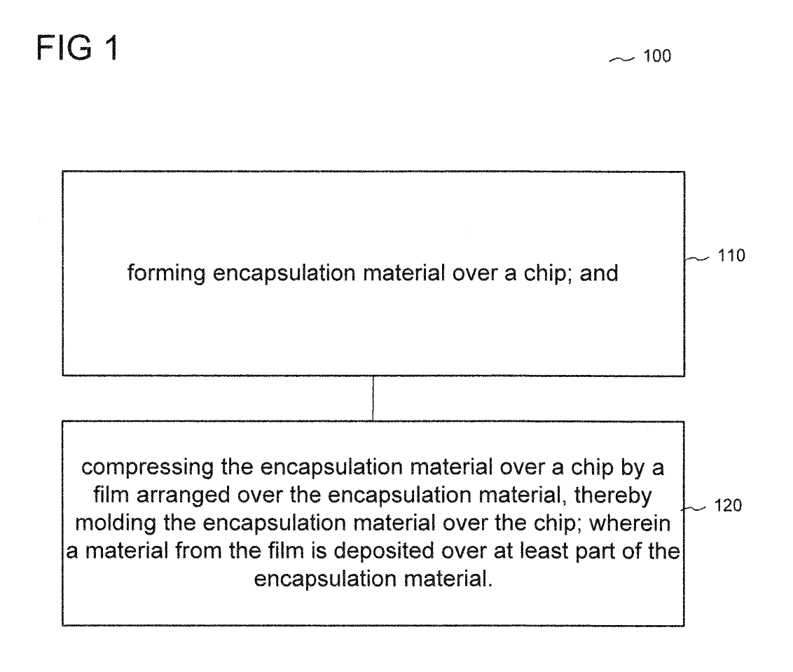

FIG. 1 shows method 100 for manufacturing a chip package. Method 100 may include:

forming encapsulation material over a chip (in 110); and

compressing the encapsulation material over a chip by a film arranged over the encapsulation material, thereby molding the encapsulation material over the chip; wherein a material from the film is deposited over at least part of the encapsulation material (in 120).

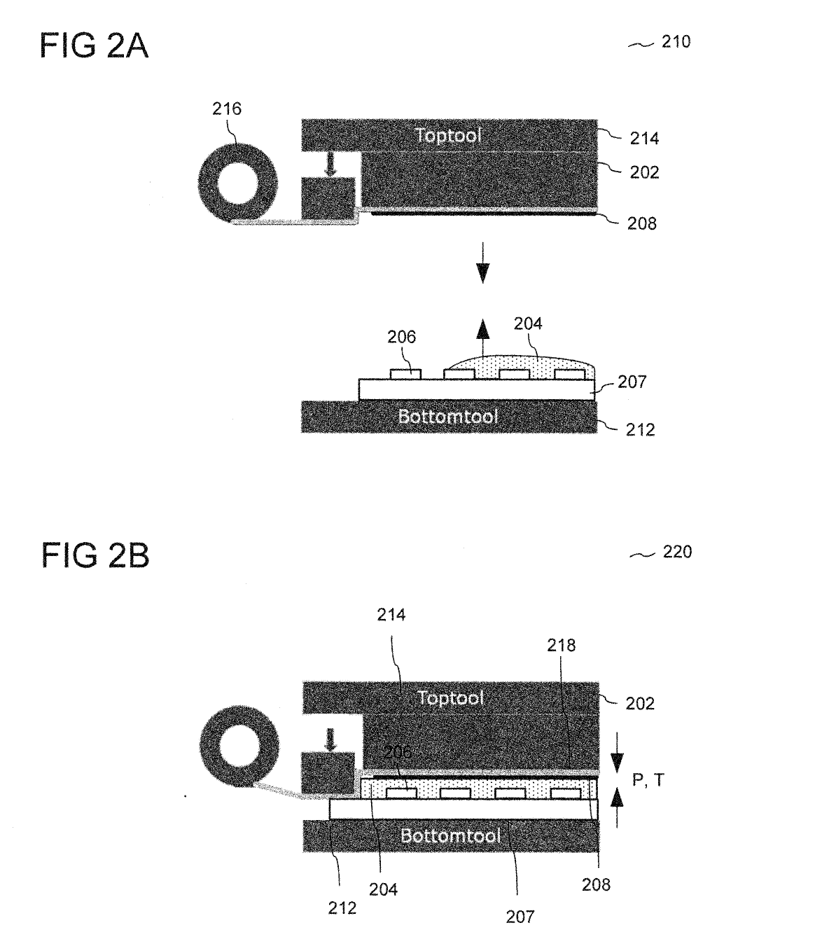

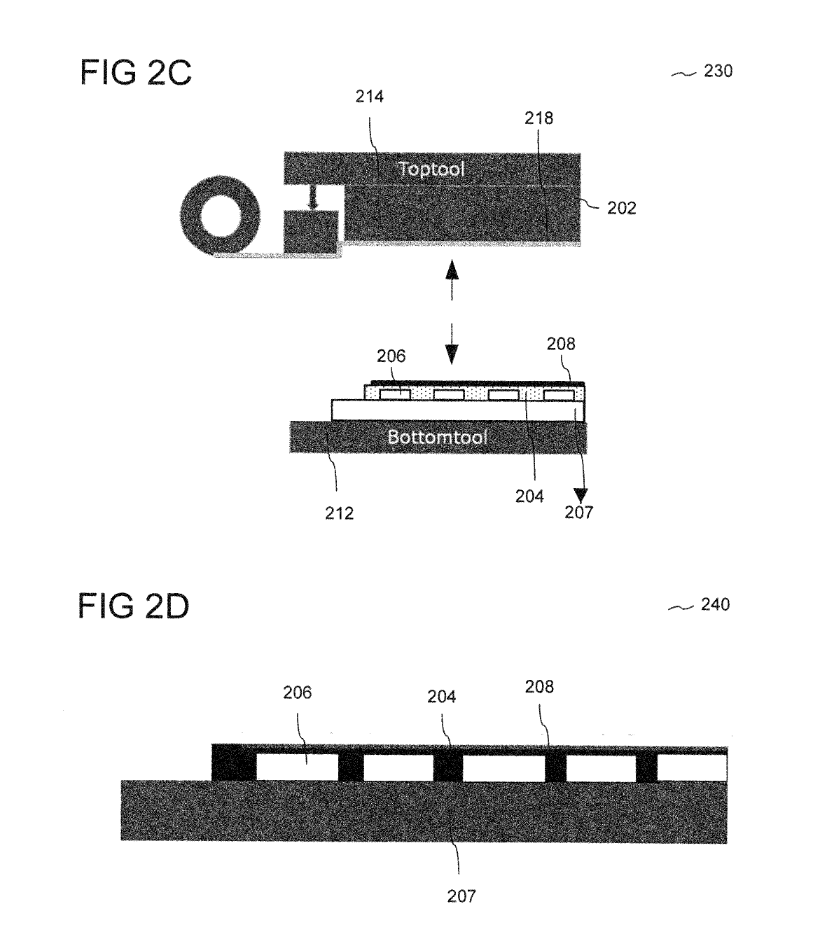

FIGS. 2A to 2C show method 200 including processes 210 to 230, for manufacturing a chip package. As shown in method 200, a compression apparatus 202, e.g. a compression molding apparatus may be configured to compress encapsulation material 204 over chip 206 by film 208 arranged over encapsulation material 204, thereby molding encapsulation material 204 over chip 206; wherein a material from film 208 may be deposited over at least part of encapsulation material 204.

As shown in FIG. 2A, compression apparatus 202 may include: a holder 212, e.g. bottom tool, for holding chip 206; a molding frame 214, e.g. top tool, configured to compress encapsulation material 204 and film 208 including an electrically conductive material over chip 204, thereby molding encapsulation material 204 over chip 206 and depositing electrically conductive material over at least part of encapsulation material 204.

It may be understood that compression molding may normally be used for depositing encapsulation material, e.g. mold material, over a chip. A compression apparatus for compression molding, may normally include a frame 212 which holds the chip or a carrier including a plurality of chips, such as a reconstituted wafer. Mold material may normally be deposited over the chip, and the frames 212, 214 may define the geometry of the mold material around the chip. Pressure and heat may be applied to the mold material, and frames 212, 214 may compress the heated mold material into the required shape and/or geometry around the chip or carrier. Mold material may be compressed over and/or around the chip by a release foil also referred to as a mold release film. The mold release film may include a film with anti-stick properties, which prevents any adhesion of the mold release film to the mold material and vice versa.

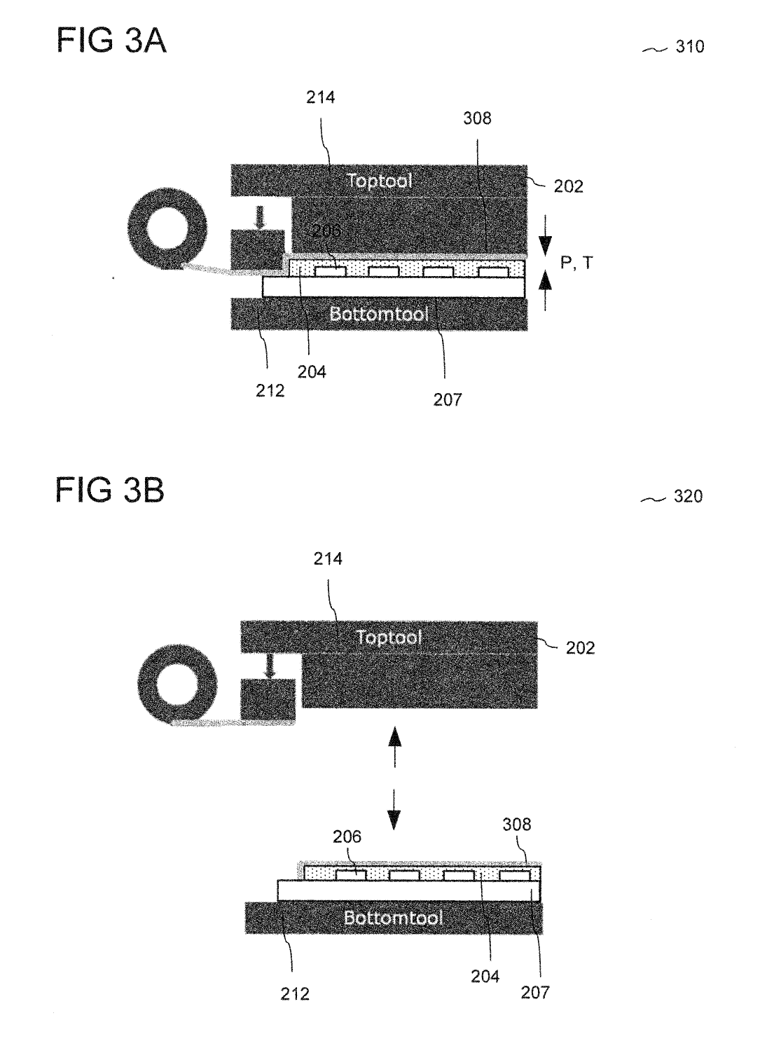

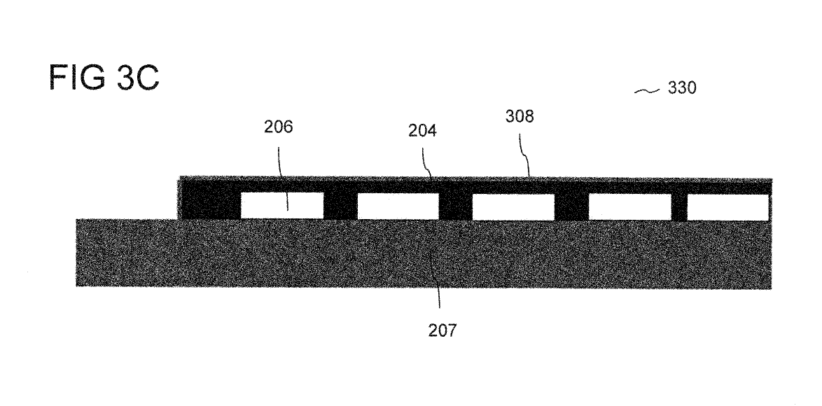

According to various embodiments, film 208 may be adhered to a traditional mold release film (FIGS. 2A to 2C), or according to other embodiments, the traditional mold release film may be replaced with film 208 (FIGS. 3A to 3C).

Method 200 may include a method for manufacturing a chip package according to various embodiments. Method 200 may include: forming encapsulation material 204 over chip 206, and subsequently compressing encapsulation material 204 over chip 206 by film 208 arranged over encapsulation material 204, thereby molding encapsulation material 204 over chip 206; wherein material from film 208 may be deposited over at least part of encapsulation material 204.

As shown in FIG. 2A, encapsulation material 204 may include an electrically insulating material, which may be deposited over chip 206 and/or chip carrier 207. At this part of the process, encapsulation material 204 may be in liquid form. At this part of the process, encapsulation material 204 may be in an un-cured form. For example, liquid encapsulation material 204 may be deposited, e.g. injected, over chip 206 and/or chip carrier 207. Encapsulation material 204 may be pre-heated before deposition over chip 206 and/or chip carrier 207, e.g. to a temperature ranging from about 100° C. and about 200° C. Molding frame 212, e.g. bottom tool 212, may function as a holder which holds chip 206 and/or chip carrier 207. It may be understood that according to various embodiments, chip carrier 207 may include a substrate on which one or more chips 206 may be arranged. One or more chips 206 may be commonly held by chip carrier 207, e.g. they may be temporarily adhered to chip carrier 207. One or more chips 206 and/or chip carrier 207 may be arranged between molding frame 212, e.g. bottom tool, and molding frame 214, e.g. top tool 214. Molding frames 212, 214 may define the geometry of encapsulation material 204 around one or more chips 206 and/or chip carrier 207. In other words, compressing encapsulation material 204 over chip 206 by film 208 arranged over encapsulation material 204, thereby molding encapsulation material 204 over chip 206, may include compressing encapsulation material 204 over carrier 207 carrying one or more chips 206 by film 208 arranged over encapsulation material 204, thereby molding encapsulation material 204 over one or more chips 206.

As shown in FIG. 2B, molding frames 212, 214 may be brought together to compress encapsulation material 204, wherein the arrangement of molding frames 212, 214 with respect to each other may defining the geometry and/or shape of encapsulation material 204 formed over one or more chips 206 and/or chip carrier 207. A pressure and temperature process may be applied to encapsulation material 204 material, and frames 212, 214 may compress the heated mold material, e.g. liquid and/or un-cured encapsulation material 204, into the required shape and/or geometry around one or more chips 206 and/or chip carrier 207 until encapsulation material 204 is set, e.g. cured; for example, at a temperature ranging from about 100° C. and about 200° C. and at a pressure ranging from about 10 bar to about 100 bar. As film 208 may be disposed over at least one of molding frames 212, 214 (in the case of FIG. 2A and 2B, film 208 may be disposed over only molding frame 214), film 208 may be compressed over encapsulation material 204 as molding frames 212,214 are brought together to compress encapsulation material 204 over one or more chips 206 and/or chip carrier 207. In other words, film 208 may be disposed over molding frame 214 and/or molding frame 212, such that film 208 may be compressed over encapsulation material 204 by molding frame 214 and/or 212.

Encapsulation material 204 may include at least one from the following group of materials, the group consisting of: filled or unfilled epoxy, pre-impregnated composite fibers, reinforced fibers, laminate, a mold material, a thermoset material, a thermoplastic material, filler particles, fiber-reinforced laminate, fiber-reinforced polymer laminate, fiber-reinforced polymer laminate with filler particles. For example, encapsulation material 204 may include a mold material. For example, encapsulation material 204 may include a resin.

Encapsulation material 204 may be compressed over chip 206 by a molding frame 214 arranged over encapsulation material 204. Encapsulation material 204 may be heated while compressing encapsulation material 204, wherein encapsulation material 204 may be shaped by molding frame 214. Encapsulation material 204 may be heated while compressing film 208 over the encapsulation material. Film 208 may be attached to a mold release film 218. Mold release film 218 may include a film or a foil which has anti-stick properties, which may prevent mold release film 218 from adhering to encapsulation material 204. Mold release film 218 may form part of a mold release roll 216, e.g. mold release film 218 may be dispensed from mold release roll 216, which may be used in a conventional compression molding apparatus for compressing mold material.

Material from film 208 and encapsulation material 204 may be deposited over chip 206 by compressing film 208 and encapsulation material 204 over chip 206. For example, film 208 may be deposited over at least part of the encapsulation material 204. Film 208 may be compressed over encapsulation material 204 during the compression of encapsulation material 204 over the chip 206, or over one or more chips 206 and/or carrier 207. Encapsulation material 204 may be introduced over one or more chips 206 before and/or while compressing encapsulation material 204 over chip 206.

Material from film 208 deposited over at least part of encapsulation material 204 may include an electrically conductive material. Material from film 208 deposited over at least part of encapsulation material 204 may include at least one from the following group of materials, the group consisting of: copper, aluminum, silver, tin, gold, palladium, zinc, nickel, iron. Film 208 may include a thickness ranging from about 5 μm to about 500 μm, e.g. about 10 μm to about 400 μm, e.g. about 50 μm to about 100 μm. Film 208 may have a higher adhesion to encapsulation material 204 than to mold release film 218. Film 208 may be compressed over encapsulation material 204 during the compression of encapsulation material 204 over chip 206. Film 208 may include an electrically conductive material, e.g. an electrically conductive foil. For example, film 208 may include a foil or sheet or film including at least one from the following group of materials, the group consisting of: copper, aluminum, silver, tin, gold, palladium, zinc, nickel, iron. For example, film 208 may include a copper foil.

According to various embodiments, as shown in FIGS. 2A to 2C, film 208 may be applied, e.g. adhered, e.g. attached to mold release film 218. For example, film 208 may be adhered to film 218, e.g. the release foil. Film 208, e.g. the copper foil, may be placed and molded in the cavity. Film 208 may have a smooth side disposed over and facing a moldtool side, e.g. disposed over molding frame 214, i.e. the smooth side faces away from encapsulation material 204. Film 208 may have a rough side which may be the side which faces encapsulation material 204 and chip 206. The rough side may be the side which is adhered to encapsulation material, as roughening is important to achieve a very good adhesion between film 208, e.g. the copper foil, and encapsulation material 204, e.g. the mold compound. Therefore, the adhesion from film 208 to encapsulation material 204, e.g. the mold compound, may be higher than the adhesion between film 208 to mold release film 218. In other words, film 208 may include roughened side, such that roughened side of film 208 may provide greater adhesion between film 208 and encapsulation material 204 than adhesion between film 208 and mold release film 218. This process makes it possible to embed and/or adhere very thick copper foils, e.g. copper foils thicker than 30 μm. Mold release film 218 when coated with copper tape and/or foil 208 (as opposed to being totally replaced by film 208) may lead to partly covered mold compound 204 as shown in FIG. 2B and 2C. As shown in FIG. 2C when molding frames 212, 214 are moved apart (in the direction of arrows), and compression has ceased to be applied to encapsulation material 204, then encapsulation material 204 may only be partially covered with film 208, wherein film 208 may be adhered to encapsulation material 204. Encapsulation material 204 may include materials including filler particles, e.g. granules, for faster cross-linking, wherein encapsulation material 204 may be un-cured or only partially cured during the compression process. Compression may take place for example in a vacuum ranging from about 1 mbar to about 50 mbar.

According to other embodiments, as shown in FIGS. 3A to 3C, the conventionally used mold release film 218 may be abandoned, and conventional mold release film 218 may be replaced by a film 308 including an electrically conductive material, e.g. a copper foil. Film 308 may include one or more or all of the properties already described with respect to film 208. This method may allow encapsulation material 204 to be substantially fully covered, for example, including over the side edges 318 of the encapsulation material. Film 308 may be in the top tool 214, e.g. attached to top tool 214. Film 308 may be disposed over molding frame 214, e.g. top tool 214. Film 308, i.e. a copper roll similar to that used in conventional release films, e.g. 216, may be used. Film 308, e.g. a copper foil may travel at the mold edge on which the adhesion from mold 204 to film 308 may be higher than the tensile strength. The thickness of the film 308 may be selected, such that the adhesion from mold 204 to copper 308 may be higher than the tensile strength. This method may have limitations regarding the copper thickness and composition and film 308 may for example, approximately be 8 μm thick. Bare copper tape lead to complete coated mold compound. Film 308 may have a smooth side disposed over moldtool side, e.g. disposed over molding frame 214 (smooth side faces away from encapsulation material 204) and a rough side which may be the side which faces encapsulation material 204 and chip 206. The rough side may be the side which is adhered to encapsulation material, as roughening is important to achieve a very good adhesion between film 208, e.g. the copper foil, and encapsulation material 204, e.g. the mold compound. Therefore, as shown in FIG. 3C, when molding frames 212, 214 are moved apart (in the direction of arrows), and compression has ceased to be applied to encapsulation material 204, film 308 may be deposited onto encapsulation material 204 (substantially fully over a top side, and over a side wall) and dislocated from copper roll 216 as the adhesion from encapsulation material 204 to film 308, e.g. to rough side of film 308, may be greater than the tensile strength of film 308.

Film 208, 308 may include a circuit copper foil, e.g. TW-YE foil, which may include an improved single side treated electro-deposited copper foil characterized by enhanced high temperature elongation properties [IPC-Grade 3], and thermally stable microstructure.

According to various embodiments, film 208, 308 may eventually form part of a chip package. An electrically conductive film 208, 308 may be used in various applications. For example, film 208, 308 may form at least part of an electrically conductive redistribution layer (RDL) of the chip package, wherein the RDL may be electrically connected to one or more contact pads formed over chip 206. The RDL, and hence film 208, 308, may have thickness ranging from about 1 μm to about 10 μm. For example, film 208, 308 may form at least part of an electrically conductive interconnect of a chip package. The electrically conductive interconnect, and hence film 208, 308, may have thickness ranging from about 1 μm to about 50 μm. For example, film 208, 308 may form at least part of a lead frame of a chip package. The lead frame, and hence film 208, 308, may have thickness ranging from about 50 μm to about 200 μm.

According to various other embodiments, an electrically insulating film 208, 308 may also eventually form part of a chip package. For example, film 208, 308 may form at least part of an electrically insulating and/or thermally conductive encapsulation material for chip 206. For example, film 208, 308 may include ceramic materials, e.g. aluminum oxide, e.g. aluminum nitride.

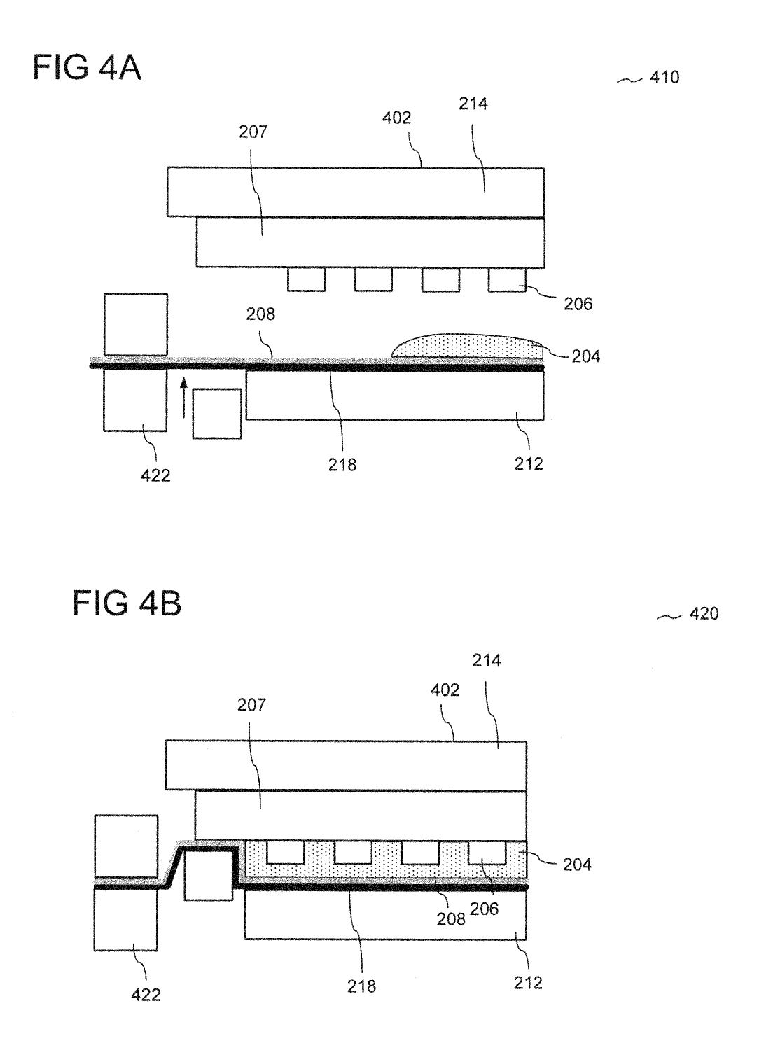

Various configurations of the compression apparatus 202 may be applied. FIGS. 2A to 2D and 3A to 3C show configurations of the compression apparatus, wherein chips 206 and/or chip carrier 207 to be molded are arranged over a bottom tool 212 and encapsulation material 204 may be formed over chips 206 and/or chip carrier 207. FIGS. 4A and 4B show a cross-sectional view of compression apparatus 402 according to other embodiments. Mold release film 218 and film 208 or alternatively film 308 (not shown) without mold release film 218, may be held by a frame 422. Encapsulation material 204 may be formed over film 208, e.g. in un-cured form. Chips 206 and/or chip carrier 207 may be held by top tool 214. Compression may be carried out and encapsulation material 204 may be brought into contact with chips 206 and/or chip carrier 207. After compression, a encapsulation material 204 (in cured form) may be formed over chips 206 and/or chip carrier 207; and film 208 may be adhered to encapsulation material 204.

Various embodiments provide a method for manufacturing a chip package, the method including: forming encapsulation material over a chip; and compressing the encapsulation material over a chip by a film arranged over the encapsulation material, thereby molding the encapsulation material over the chip; wherein a material from the film is deposited over at least part of the encapsulation material.

According to an embodiment, the encapsulation material includes an electrically insulating material.

According to an embodiment, the encapsulation material includes at least one from the following group of materials, the group consisting of: filled or unfilled epoxy, pre-impregnated composite fibers, reinforced fibers, laminate, a mold material, a thermoset material, a thermoplastic material, filler particles, fiber-reinforced laminate, fiber-reinforced polymer laminate, fiber-reinforced polymer laminate with filler particles.

According to an embodiment, the method further includes compressing the encapsulation material over the chip by a molding frame arranged over the encapsulation material.

According to an embodiment, the method further includes heating the encapsulation material while compressing the encapsulation material wherein the encapsulation material is shaped by the molding frame.

According to an embodiment, the method further includes heating the encapsulation material while compressing the film over the encapsulation material.

According to an embodiment, material from the film and the encapsulation material are deposited over the chip by compressing the film and the encapsulation material over the chip.

According to an embodiment, the method further includes introducing encapsulation material over the chip while compressing the encapsulation material over the chip.

According to an embodiment, the material deposited over at least part of the encapsulation material includes an electrically conductive material.

According to an embodiment, the material deposited over at least part of the encapsulation material includes an electrically insulating material.

According to an embodiment, the material deposited over at least part of the encapsulation material includes at least one from the following group of materials, the group consisting of: copper, aluminum, silver, tin, gold, palladium, zinc, nickel, iron.

According to an embodiment, the film includes a thickness ranging from about 5 μm to about 500 μm.

According to an embodiment, the film is deposited over at least part of the encapsulation material.

According to an embodiment, the film is compressed over the encapsulation material during the compression of the encapsulation material over the chip.

According to an embodiment, the film includes a copper foil.

According to an embodiment, the film is attached to a mold release film.

According to an embodiment, the film has a higher adhesion to the encapsulation material than to the mold release film.

According to an embodiment, the method further includes disposing the film over the molding frame, such that the film is compressed over the encapsulation material by the molding frame.

According to an embodiment, the film includes a roughened side, such that the roughened side of the film provides a greater adhesion between the film and the encapsulation material than the adhesion between the film and the mold release film.

According to an embodiment, compressing the encapsulation material over the chip by a film arranged over the encapsulation material, thereby molding the encapsulation material over the chip includes compressing the encapsulation material over a carrier carrying one or more chips by a film arranged over the encapsulation material, thereby molding the encapsulation material over the one or more chips.

According to an embodiment, compressing the encapsulation material over a chip by a film arranged over the encapsulation material, includes compressing the encapsulation material over a chip by a film arranged over the encapsulation material in a compression molding process.

According to an embodiment, compressing the encapsulation material over a chip by a film arranged over the encapsulation material, includes compressing the encapsulation material over a chip by a film arranged over the encapsulation material in a transfer molding process.

Various embodiments provide a method for manufacturing a chip package, the method including: forming encapsulation material over a chip; compressing the encapsulation material over a chip by a film including an electrically conductive material, thereby molding the encapsulation material over the chip; wherein the electrically conductive material is deposited over at least part of the encapsulation material.

Various embodiments provide a compression apparatus including: a holder for holding a chip; a molding frame configured to compress an encapsulation material and a film including an electrically conductive material over a chip, thereby molding the encapsulation material over the chip and depositing the electrically conductive material over at least part of the encapsulation material.

Various embodiments provide a method for manufacturing a wafer level package, the method including: forming encapsulation material over one or more chips; compressing, by a film including an electrically conductive material, the encapsulation material over one or more chips arranged over a carrier, thereby at least partially surrounding the one or more chips with the encapsulation material; and adhering the film to the encapsulation material.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A method for manufacturing a chip package, the method comprising:
forming encapsulation material over a chip; and
compressing the encapsulation material over a chip by a by a molding frame and by a film arranged over the encapsulation material, thereby molding the encapsulation material over the chip, the molding frame including a release film attached to the film;
removing an upper portion of the molding frame from the encapsulation material;
wherein the film is released from the release film and is deposited over at least part of a top side of the encapsulation material.

2. The method according to claim 1,
wherein the encapsulation material comprises an electrically insulating material.

3. The method according to claim 1,
wherein the encapsulation material comprises at least one from the following group of materials, the group consisting of filled or unfilled epoxy, pre-impregnated composite fibers, reinforced fibers, laminate, a mold material, a thermoset material, a thermoplastic material, filler particles, fiber-reinforced laminate, fiber-reinforced polymer laminate, fiber-reinforced polymer laminate with filler particles.

4. (canceled)

5. The method according to claim 4, further comprising
heating the encapsulation material while compressing the encapsulation material wherein the encapsulation material is shaped by the molding frame.

6. The method according to claim 1, further comprising
heating the encapsulation material while compressing the film over the encapsulation material.

7. The method according to claim 1,
wherein the film and the encapsulation material are deposited over the chip by compressing the film and the encapsulation material over the chip.

8. The method according to claim 1,
further comprising introducing encapsulation material over the chip while compressing the encapsulation material over the chip.

9. The method according to claim 1,
wherein the film deposited over at least part of the encapsulation material comprises an electrically conductive material.

10. The method according to claim 1,
wherein the film deposited over at least part of the encapsulation material comprises an electrically insulating material.

11. The method according to claim 1,
wherein the film deposited over at least part of the encapsulation material comprises at least one from the following group of materials, the group consisting of copper, aluminum, silver, tin, gold, palladium, zinc, nickel, iron.

12. The method according to claim 1,
wherein the film comprises a thickness ranging from about 5 μm to about 500 μm.

13. (canceled)

14. The method according to claim 1,
wherein the film is compressed over the encapsulation material during the compression of the encapsulation material over the chip.

15. The method according to claim 14,
wherein the film comprises a copper foil.

16. (canceled)

17. The method according to claim 1,
wherein the film has a higher adhesion to the encapsulation material than to the release film.

18. The method according to claim 1,
further comprising disposing the film over the molding frame, such that the film is compressed over the encapsulation material by the molding frame.

19. The method according to claim 1,
wherein the film comprises a roughened side, such that the roughened side of the film provides a greater adhesion between the film and the encapsulation material than the adhesion between the film and the release film.

20. The method according to claim 1,
wherein compressing the encapsulation material over the chip by a molding frame and by a film arranged over the encapsulation material, thereby molding the encapsulation material over the chip comprises
compressing the encapsulation material over a carrier carrying one or more chips by a film arranged over the encapsulation material, thereby molding the encapsulation material over the one or more chips.

21. The method according to claim 1,
wherein compressing the encapsulation material over a chip by a molding frame and by a film arranged over the encapsulation material, comprises
compressing the encapsulation material over a chip by a film arranged over the encapsulation material in a compression molding process.

22. The method according to claim 1,
wherein compressing the encapsulation material over a chip by a molding frame and by a film arranged over the encapsulation material, comprises
compressing the encapsulation material over a chip by a film arranged over the encapsulation material in a transfer molding process.

23. A method for manufacturing a chip package, the method comprising:
forming encapsulation material over a chip;
compressing the encapsulation material over a chip by a molding frame and by a film comprising an electrically conductive material, thereby molding the encapsulation material over the chip;
removing an upper portion of the molding frame from the encapsulation material after compressing,
wherein the film is deposited over at least part of a top side of the encapsulation material and is at least partially embedded in the encapsulation material.

24. A compression apparatus comprising:
a holder for holding a chip;
a molding frame configured to compress an encapsulation material and a film comprising an electrically conductive material over a chip, thereby molding the encapsulation material over the chip and depositing the electrically conductive material over at least part of the encapsulation material.

25. A method for manufacturing a wafer level package, the method comprising:
forming encapsulation material over one or more chips;
compressing, by a molding frame and by a film comprising an electrically conductive material, the encapsulation material over one or more chips arranged over a carrier, thereby at least partially surrounding the one or more chips with the encapsulation material, the molding frame including a mold release film attached to the film, the mold release film dispensed from a mold release roll;
adhering the film to the encapsulation material; and
removing the molding frame from the encapsulation material after adhering the film to the encapsulation material,
wherein the adhered film is released from the mold release film.

26. The method of claim 1,
wherein the film released from the release film is further deposited over at least part of a side wall of the encapsulation material.

27. The method of claim 23,
wherein the film is further deposited over at least part of a side wall of the encapsulation material.
